(19) United States
(12) Patent Application Publication
(10) Pub. No.: US 2005/0145873 A1
(43) Pub. Date: Jul. 7, 2005

(54) Light-emitting diode

(76) Inventors: Shyi-Ming Pan, Chuang-Hua City (TW); Fen-Ren Chien, Yung-Ho City (TW); Lung-Chien Chen, Hsin-Chuang City (TW)

Correspondence Address: SUPREME PATENT SERVICES, POST OFFICE BOX 2339, SARATOGA, CA, 95070, US

(21) Appl. No.: 10/750,784

(22) Filed: Jan. 3, 2004

(51) Int. Cl. H01L 33/00

(52) U.S. Cl. 257/103; 257/98

(57) ABSTRACT

A light-emitting diode device is provided with the following manufacturing method: forming an n-GaN layer on a substrate; growing an SiO₂ layer on the n-GaN surface, and using the photo-lithography process to expose the n-GaN within the mesa area; using MOCVD to grow an LED structure in the epitaxy within the mesa area, the formed structure being a p-n coplanar structure due to the selective area characteristic; and finally, forming the electrodes on the structure to complete an LED device. The device can be manufactured without the etching process to form the p-n coplanar structure. In comparison to other conventional manufacturing methods, the method simplifies the manufacturing process, and avoids many problems associated with etching, including non-uniform etching, overly rough surface, etching damages, and current leakage. Furthermore, SiO₂ is used as a scattering layer to prevent emitted light from internally reflected, and therefore, improves the external quantum efficiency.

### FIELD OF THE INVENTION

The present invention relates to a light-emitting diode (LED) based on an n-GaN layer and, more particularly, to a light-emitting diode based on an InAlGaN layer.

### BACKGROUND OF THE INVENTION

As most GaN-based semiconductor material is grown on the non-conductive sapphire substrate, the conventional technique in manufacturing LED uses etching to fabricate the electrodes on the same side. However, the conventional wet etching technique is not suitable for GaN-based material because the GaN-based material is highly resistant to acid and alkaline. The conventional wet etching is too slow in etching the GaN-based material for mass production. Therefore, the dry etching technique is used instead. For example, the World Patent No. WO09,854,757 disclosed a dry etching method for III-V group semiconductor material. Although the dry etching techniques overcomes the drawbacks of the wet etching technique, the dry etching is easy to damage the epitaxy layer, which results in another set of problems, such as non-uniformity in etching, rough etched surface, damage-induced poor electrical characteristics (as discussed in the article of Journal of Electronic Materials, 27, No. 4, 261, 1998), and current leakage due to the etching of mesa sidewall (as in Appl. Phys. Lett. 72, 742, 1998, and Jpn. J. Appl. Phys. 37, L1202, 1998). Therefore, to manufacture the LED on the GaN-based material, it is important to solve the problems caused by etching.

Furthermore, because of the refraction index difference between the III-V group semiconductor GaN (n=2.3) and the air (n=1), the full reflection threshold angle is only about 25°. This causes most of the light from the light-emitting layer to be reflected internally, instead of emitting. To improve this type of surface structure, a roughening technique is proposed to perform on the surface so that the light is scattered and changes its path when it reaches the roughened surface. This increases the probability of the light emitting, and the external quantum efficiency can be raised as high as 40%, as disclosed in IEEE Transactions on Electron Devices, 47(7), 1492, 2000. The conventional roughening technique uses the etching on the epitaxy surface. For example, U.S. Pat. No. 5,040,044 disclosed a method of using chemical etching for roughening the surface of the light-emitting devices for improving the external quantum efficiency. Other related patents include U.S. Pat. Nos. 5,429,954, and 5,898,192. However, while the above techniques are only applicable to manufacturing the red LED because the material is easier to process, it is not suitable to the GaN-based material because it is highly resistant to acid and alkaline. On the other hand, the dry etching, although overcoming the problems caused by the wet etching, can easily damage the epitaxy layer, and more particularly, the resistance of the p-GaN may increase. In addition, as the P-GAN is usually thin (0.1-0.3 μm), a direct roughening on the p-GaN can even damage the light-emitting layer and reduce the area for light emitting. Because the transparent electrode of the GaN LED must be very thin (10 nm) for light penetrating, it may cause the discontinuity in the transparent electrode. The discontinuity in the transparent electrode affects the current distribution, which, in turn, will reduce the external quantum efficiency. In other words, unless p-GaN is thick, it is hard to perform the roughening directly on the p-GaN surface.

Therefore, a need has arisen for an LED manufacturing process to overcome the aforementioned restrictions imposed by the conventional techniques.

### SUMMARY OF THE INVENTION

To solve the problems associated with the conventional techniques, the present invention provides a method that does not require the etching process to expose the n-GaN layer. The present invention discloses a method for manufacturing GaN-based light-emitting devices. In comparison to the light-emitting devices manufactured with other methods, the light-emitting devices of the present invention avoid the problems associated with etching process.

The present invention grows an SiO₂ interface layer on top of the epitaxically grown n-GaN layer, and uses the photo-lithography to form a mesa on the SiO₂ surface. The SiO₂ within the mesa area is then removed to expose the n-GaN layer, and the MOCVD method is used to epitaxically grow the LED structure in the mesa area. Using the characteristics of the selectively grown GaN, the structure is grown to be p-n coplanar. Finally, the SiO₂ is removed to obtain the p-n coplanar LED structure. Because the present invention does not use etching process to achieve the p-n coplanar structure required by the LED devices, it avoids the problems associated with the etching process.

In addition, to solve the internal reflection problems associated with the conventional techniques, the present invention discloses a method of inserting an SiO₂ layer in a part of InAlGaN layer for roughening the surface during the epitaxy growing process. This method improves the external quantum efficiency of the GaN-based light-emitting devices. The roughening technique used in the present invention is able to roughen the LED surface without roughening the p-GaN of those devices. In comparison to the other light-emitting devices manufactured with other methods, the present invention does not damage the p-GaN or light-emitting layer to improve the external quantum efficiency.

The main feature of the present invention is to use photo-lithography to form trenches on the surface after growing the InAlGaN layer on the expitaxy. A part of the area also has the InAlGaN removed to expose the substrate. An SiO₂ layer is grown in the trenches. Finally, an LED structure is grown on top to form a light-emitting device. The SiO₂ layer is used as a scattering layer to scatter the light emitted from the light-emitting layer and to reduce the full internal reflection and improve the external quantum efficiency.

These and other objects, features and advantages of the invention will be apparent to those skilled in the art, from a reading of the following brief description of the drawings, the detailed description of the preferred embodiment, and the appended claims.

### BRIEF DESCRIPTION OF THE DRAWINGS

FIGS. 1a-1e show a manufacturing process of a first embodiment of the present invention of a GaN LED device.

FIGS. 2a-2f show a manufacturing process of a second embodiment of the present invention of an InAlGaN LED device.

FIGS. 3a-3f show a manufacturing process of a third embodiment of the present invention of an InAlGaN LED device.

### DETAILED DESCRIPTION OF THE PERFERRED EMBODIMENT

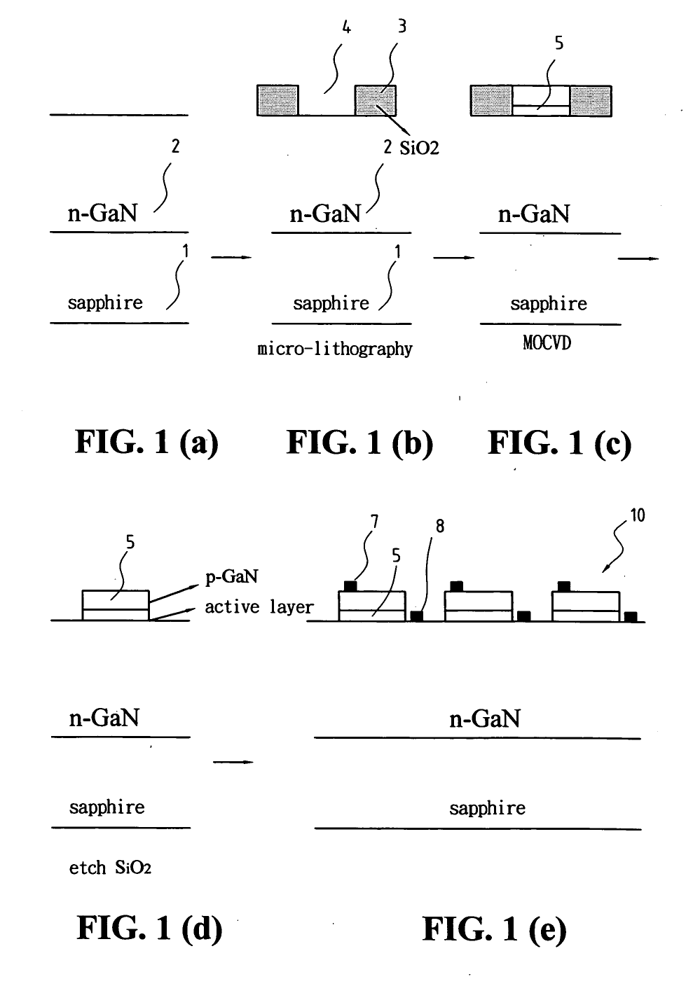

FIGS. 1a-1e show the manufacturing process of a first embodiment of the present invention of a GaN LED device. A sapphire substrate 1 is placed in an MOCVD system to grow a GaN buffer layer 2 of 20-50 nm thick at the temperature of 500-600° C. Then, raise the temperature of substrate 1 to 1000-1200° C. to grow a Si-doped GaN layer of 2-4 μm thick. Remove the chip from the MOCVD system, and grow a 05-11 μm SiO₂ layer 3 in the PECVD system. Use the photo-lithography to remove the SiO₂ in the mesa area 4, and place the chip in the MOCVD system at the temperature of 700-900° C. to grow an InGaN/GaN multiple quantum well (MQW) structure 5 in mesa area 4 for the light-emitting layer. Then, raise the temperature of substrate 1 to 1000-1200° C. to grow an Mg-doped GaN contact layer of 0.1-0.2 μm thick. Remove the chip from the MOCVD system, and remove the SiO₂ outside of mesa area 4 to complete a p-n coplanar LED epitaxy 10. Use Ni/Au to form the p-type ohm contact electrode 7 on the p-GaN surface, and Ti/Al to form the n-type ohm contact electrode 8 on the n-GaN surface to complete the LED chip.

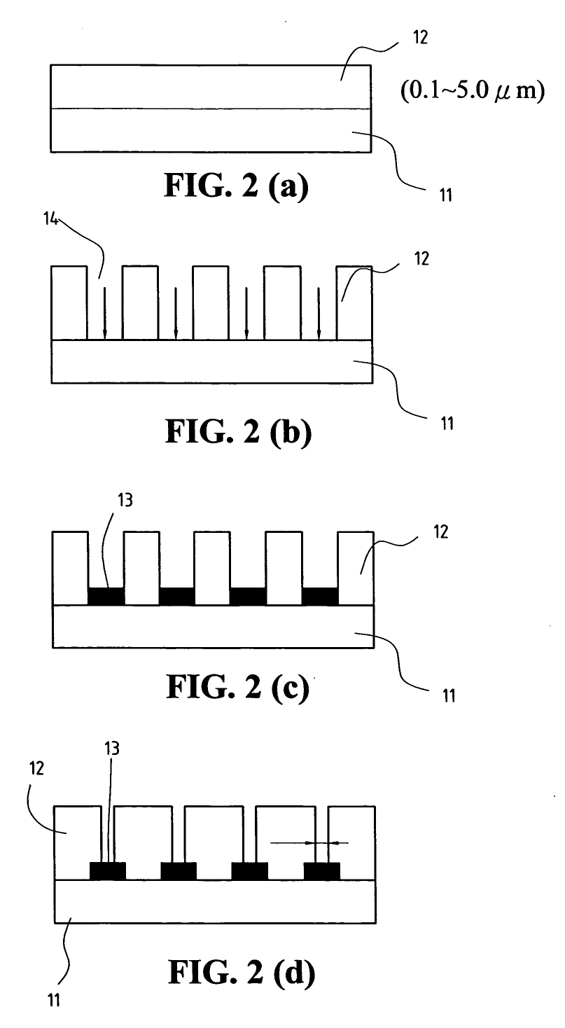

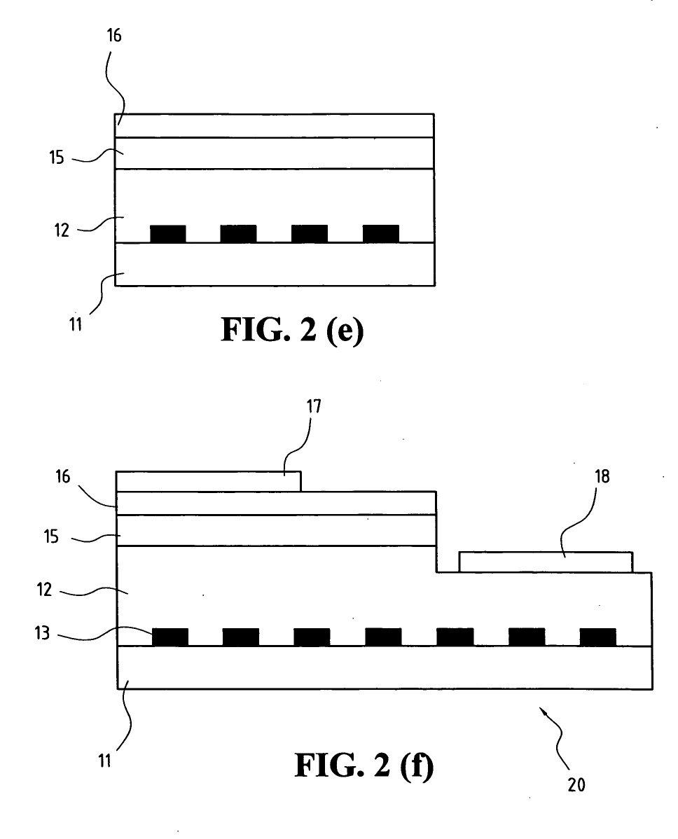

FIGS. 2a-2f show the manufacturing process of a second embodiment of the present invention of an InAlGaN LED device. A sapphire substrate 11 is placed in an MOCVD system to grow an InAlGaN layer 12 of thickness greater than 0.1 μm. Remove the chip from the MOCVD system, and use the photo-lithography and dry etching to etch trenches 14 on InAlGaN buffer layer 12. The depth of trenches 14 is the thickness of InAlGaN layer 12. Grow an SiO₂ 13 layer in trenches 14, and place the chip in the MOCVD system at the temperature of 800-1200° C. to grow an Si-doped InAlGaN layer of 1-2 μm. Lower the temperature of substrate 11 to 700-900° C., and grow an InGaN/GaN multiple quantum well (MQW) structure 15 for the light-emitting layer. Then, raise the temperature of substrate 11 to 1000-1200° C. to grow an Mg-doped GaN contact layer 16 of 0.1-0.2 μm thick. This completes an LED epitaxy 20. Use the dry etching to remove a part of p-GaN 16 and MQW 15 to expose the n-GaN surface. Use Ni/AU to form the p-type ohm contact electrode 17 on the p-GaN surface, and Ti/Al to form the n-type ohm contact electrode 18 on the n-GaN surface to complete the LED chip.

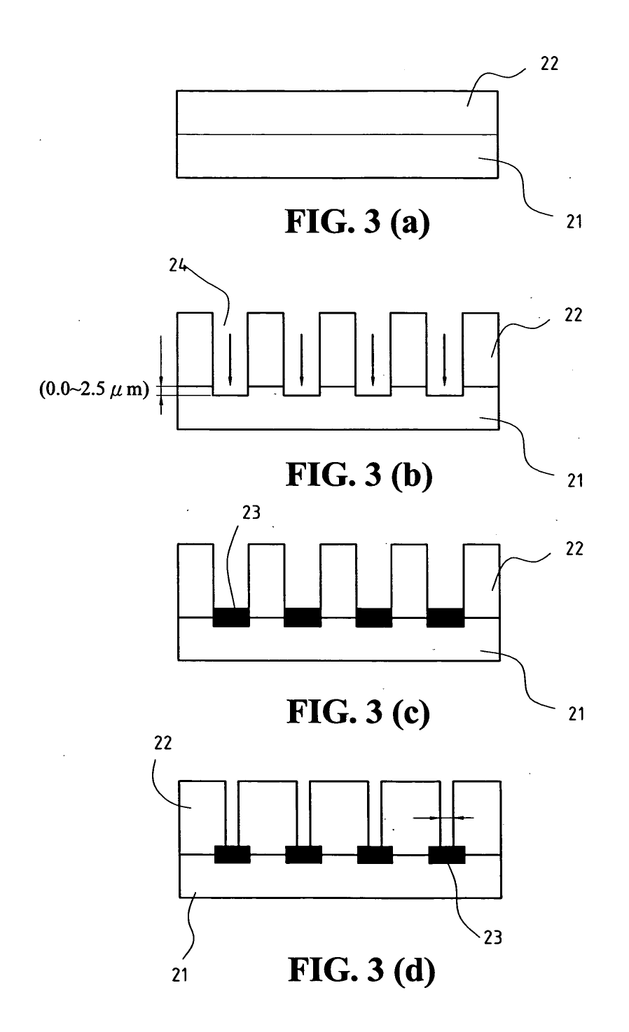

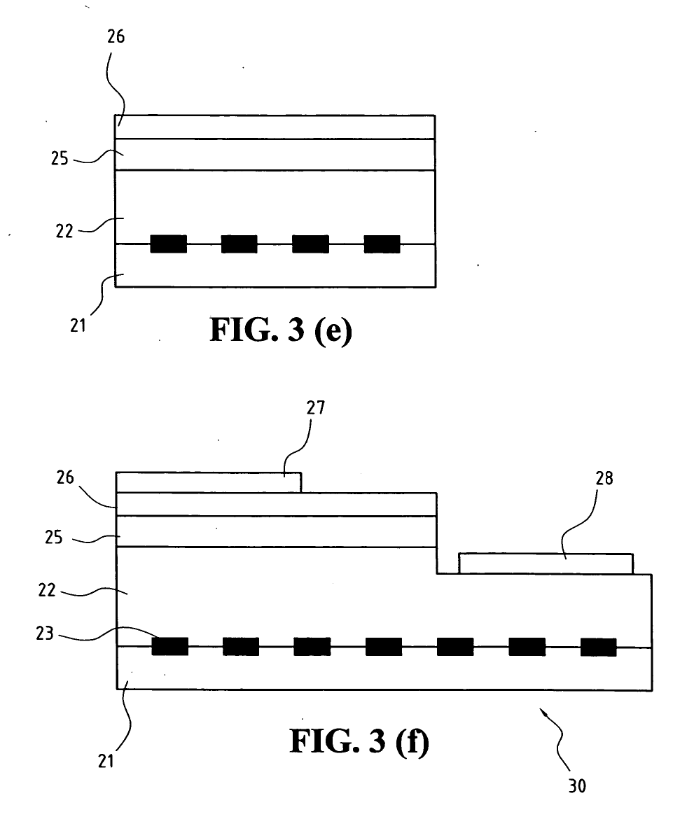

FIGS. 3a-3f show the manufacturing process of a third embodiment of the present invention of an InAlGaN LED device. A sapphire substrate 21 is placed in an MOCVD system to grow an InAlGaN layer 22 of thickness greater than 0.1 μm. Remove the chip from the MOCVD system, and use the photo-lithography and dry etching to etch trenches 24 on InAlGaN buffer layer 22. The depth of trenches 14 is 0.2-5 μm more than the thickness of InAlGaN layer 22. Grow an SiO₂ 23 layer in trenches 24, and place the chip in the MOCVD system at the temperature of 800-1200° C.° C. to grow an Si-doped InAlGaN layer of 1-2 μm. Lower the temperature of substrate 21 to 700-900° C., and grow an InGaN/GaN multiple quantum well (MQW) structure 25 for the light-emitting layer. Then, raise the temperature of substrate 21 to 1000-1200° C. to grow an Mg-doped GaN contact layer 26 of 0.1-0.2 μm thick. This completes an LED epitaxy 30. Use the dry etching to remove a part of p-GaN 26 and MQW 25 to expose the n-GaN surface. Use Ni/Au to form the p-type ohm contact electrode 27 on the p-GaN surface, and Ti/Al to form the n-type ohm contact electrode 28 on the n-GaN surface to complete the LED chip.

While the invention has been described in connection with what is presently considered to the most practical and preferred embodiments, it is to be understood that the invention is not to be limited to the disclosed embodiments, but, on the contrary, it should be clear to those skilled in the art that the description of the embodiment is intended to cover various modifications and equivalent arrangement included within the spirit and scope of the appended claims.

1. A light-emitting diode (LED) device, comprising:
a substrate;
a first semiconductor layer, formed on top of the substrate;
an insulating layer, formed on top of the first semiconductor layer;
a mesa area, formed on the insulting layer and exposing the surface of the first semiconductor layer; and
an LED structure formed on the exposed surface of the first semiconductor layer;
where the LED structure being a light-emitting active layer and a p-type GaN III-V group compound layer, the p-type GaN III-V group compound layer being connected to a p-type low-resistance ohm contact, and an n-type GaN III-V group compound layer being connected to an n-type low-resistance ohm contact to provide a forward bias.

2. The LED device as claimed in claim 1, wherein the substrate is selected from the group consisting of sapphire, SiC, Si, GaAs, LiAlO₂, LiGaO₂, AlN.

3. The LED device as claimed in claim 1, wherein the first semiconductor layer is an n-type semiconductor layer.

4. The LED device as claimed in claim 1, wherein the first semiconductor layer is an AlₓGa_{(1-x-y)}In_{y}N thick film, with 0≦x,y<1, 0≦x+y<1.

5. The LED device as claimed in claim 1, wherein the insulating layer at least comprises a material selected from a group consisting of SiO₂, SiN, AlN, TiN, Al₂O₃ and a combination thereof.

6. The LED device as claimed in claim 1, wherein the insulating layer is made of metal, alloy, or their combination.

7. The LED device as claimed in claim 1, wherein the insulating layer is fabricated with an e-gun, sputter, or CVD method.

8. The LED device as claimed in claim 1, wherein the insulating layer has the thickness greater than 0.1 μm.

9. The LED device as claimed in claim 1, wherein the mesa area is formed with a photo-lithography process.

10. The LED device as claimed in claim 1, wherein the light-emitting active layer is a P-N junction, DH, SQW, or MQW structure.

11. A light-emitting diode (LED) device, comprising:
a substrate;
a first semiconductor layer, formed on top of the substrate;
a plurality of trenches, formed in a part of area of the first semiconductor layer;
an insulating layer, formed in the trenches; and
an LED structure formed on the exposed surface of the first semiconductor layer;
where the LED structure being a light-emitting active layer and a p-type GaN III-V group compound layer, the p-type GaN III-V group compound layer being connected to a p-type low-resistance ohm contact, and an n-type GaN III-v group compound layer being connected to an n-type low-resistance ohm contact to provide a forward bias.

12. The LED device as claimed in claim 11, wherein the substrate is selected from a group consisting of sapphire, SiC, Si, GaAs, LiAlO₂, LiGaO₂, AlN.

13. The LED device as claimed in claim 11, wherein the first semiconductor layer is an AlₓGa_{(1-x-y)}In_{y}N thick film, with 0≦x,y≦1, 0≦x+y<1.

14. The LED device as claimed in claim 11, wherein the first semiconductor layer has the thickness greater than 0.1 μm.

15. The LED device as claimed in claim 11, wherein the method of forming the trenches on the first semiconductor layer comprises at least one of the following methods: photo-lithography or laser processing.

16. The LED device as claimed in claim 11, wherein the method of forming the trenches on the first semiconductor layer comprises at least one of the following methods: wet etching or dry etching.

17. The LED device as claimed in claim 11, wherein the depth of the trenches on the first semiconductor layer is less than or equal to the thickness of the first semiconductor layer.

18. The LED device as claimed in claim 11, wherein the depth of the trenches on the first semiconductor layer is greater than the thickness of the first semiconductor layer.

19. The LED device as claimed in claim 11, wherein the shape of the trenches on the first semiconductor layer comprises at least one of the following or their combination: rectangle, triangle, circle, and polygon.

20. The LED device as claimed in claim 11, wherein the insulating layer is selected from a group consisting of SiO₂, Si₃N₄, AlN, TiN, TiO₂ and a combination thereof.

21. The LED device as claimed in claim 11, wherein the insulating layer is made of metal, alloy, or their combination.

22. The LED device as claimed in claim 11, wherein the insulating layer has the thickness greater than 0.1 μm.

23. The LED device as claimed in claim 11, wherein the light-emitting active layer is a P-N junction, DH, SQW, or MQW structure.
